(19) United States
(12) Patent Application Publication
(10) Pub. No.: US 2006/0180887 A1
(43) Pub. Date: Aug. 17, 2006

(54) Semiconductor device and production method thereof

(75) Inventor: Atsushi Ono, Yamatokoriyama-shi (JP)

Correspondence Address: NIXON & VANDERHYE, PC, 901 NORTH GLEBE ROAD, 11TH FLOOR, ARLINGTON, VA, 22203, US

(73) Assignee: SHARP KABUSHIKI KAISHA, Osaka (JP)

(21) Appl. No.: 11/352,292

(22) Filed: Feb. 13, 2006

(30) Foreign Application Priority Data
Feb. 15, 2005 (JP) 2005-038395

(51) Int. Cl. H01L 31/0232

(52) U.S. Cl. 257/432

(57) ABSTRACT

In a semiconductor device, a spacer layer is formed around an imaging element on a semiconductor substrate and a glass lid is combined to the spacer layer via an adhesive layer. A space is made between the semiconductor substrate and the glass lid so as to be positioned at a region where the imaging element is disposed. As a result, in forming a hollow section between a light transmitting material and an active element on the semiconductor substrate, it is unnecessary to apply a large load and to superimpose patterns when the light transmitting material is combined to the semiconductor substrate.

This non-provisional application claims priority under 35 U.S.C. §119(a) on Patent Application No. 38395/2005 filed in Japan on Feb. 15, 2005, the entire contents of which are hereby incorporated by reference.

### FIELD OF THE INVENTION

The present invention relates to a semiconductor device including (i) a semiconductor substrate in which a semiconductor element and a penetrating electrode are formed and (ii) a light transmitting material attached to the semiconductor substrate, the semiconductor device being preferably used for a light reception sensor such as a CCD and a CMOS imager, and to a production method thereof.

### BACKGROUND OF THE INVENTION

A package of a light receiving sensor of a conventional CCD, a CMOS imager, or the like has a structure illustrated in FIG. 6. According to the structure, a semiconductor chip 101 is die-bonded, via a die bond material 117, in a hollow case 115 made of ceramic or resin, an electrode pad 109 is electrically connected with an electrode lead 116 via a wire 118, and a glass lid 112 is attached to the hollow case 115 via an adhesive 119 so that the hollow case 115 is sealed. Further, an imaging element 113 is formed on the semiconductor chip 101 and a micro lens section 114 is formed on the imaging element 113.

Further, a conventional sensor module using a light reception sensor such as a CCD, a CMOS imager, or the like has a structure illustrated in FIG. 7. According to the structure, the semiconductor chip 101 is die-bonded on a substrate 120 via the die bond material 117, and the electrode pad 109 is electrically connected with an electrode 121 on the substrate 120 via the wire 118. Further, the substrate 120 has a face, having the semiconductor chip 101, which is covered by a package 122. An opening of the package 122 is sealed by a glass lid 112 and a holder 124 having a lens 123.

Under such techniques, recently, there have been increasing needs for downsizing a package for the purpose of high density packaging of a light reception sensor package or a module. However, because a sensor of a light reception sensor is formed on a major part of the surface of a semiconductor, it is impossible to realize a wafer level CSP (Chip Size Package) in which a rewiring and packaging terminal is formed on the surface of the wafer. Further, as disclosed in each of Document 1 (Japanese Unexamined Patent Publication No. 94082/2002 (Tokukai 2002-94082); published on Mar. 29, 2002) and Document 2 (Japanese Unexamined Patent Publication No. 207461/2004 (Tokukai 2004-207461); published on Jul. 22, 2004), there is provided a semiconductor chip in which a penetrating electrode penetrates the semiconductor chip from a front face to a back face and a rewiring and packaging terminal is formed on the back face, and the semiconductor chip is applied to a light reception sensor.

However, there is the following problem in forming the penetrating electrode in a light reception sensor.

In order to prevent attachment of foreign substances and scars on the light reception sensor, it is necessary to attach a light transmitting material such as glass on the light reception sensor so as to seal the light reception sensor.

In forming the structure described in Document 1, penetrating holes are formed in a wafer, wiring and solder balls are formed on the back face of the wafer, and optical glass (light transmitting material) is attached to the wafer via an adhesive made of transparent resin or low-melting glass. After that, the wafer and the optical glass are cut together by use of dicing, thereby obtaining semiconductor chips.

However, in a case of a device which increases its sensibility by forming a micro lens for collecting light on an upper part of an imaging element, the following problem may occur when the device is formed according to the aforementioned process. The problem is such that: because there exists on the micro lens the adhesive made of transparent resin or low-melting glass used to attach the optical glass (light transmitting material), it is impossible to collect light. This is explained below. The reflective index of acryl resin used for the micro lens is approximately 1.5. Because the reflective index of the air is approximately 1.0, light having been incident from the air to the micro lens is collected. On the other hand, the reflective index of low-melting glass or an adhesive (such as epoxy resin) is approximately 1.5, namely, substantially the same as that of acryl. As a result, light having been incident from the low-melting glass or the adhesive is not collected. As such, imaging is difficult. Therefore, a space between the optical glass and the micro lens has to be hollow.

On the other hand, in order to attach the optical glass to the wafer so that the space between the optical glass and the micro lens is hollow, a method described in Document 2 is used for example. According to the method, the hollow is made by patterning, through photolithography, an organic material such as photosensitive epoxy resin or polyimide provided as an adhesive layer on the optical glass so that an air gap (a hollow part) is made. Subsequently, the optical glass is attached to the wafer after alignment.

However, according to the method, the adhesive layer made of the organic material such as photosensitive epoxy resin or polyimide has its light response part hardened when patterning is performed. Therefore, in order to attach the adhesive layer to the wafer and consolidate the layer, a pressure of 1 through 2 MPa is necessary. For example, when a half area of an 8-inch wafer is occupied by the adhesive layer, it is necessary to apply a load being approximately 3 t onto the wafer. Therefore, it is difficult to evenly attach the adhesive layer to the wafer.

Further, because the adhesive layer is formed on the optical glass, it is necessary to accurately superimpose the pattern of the optical glass on the pattern of the wafer (this process is referred to as alignment). Therefore, there is a case where the pattern of the optical glass is not superimposed on the pattern of the wafer, with a result that problems may occur in later steps.

### SUMMARY OF THE INVENTION

An object of the present invention is to provide a semiconductor device that allows an optical glass to be combined to a wafer without adding a large load and that makes it unnecessary to superimpose the pattern of the optical glass with the pattern of the wafer in the combination, so as to obtain a structure for forming a hollow section between the optical glass and a micro lens on the wafer.

In order to achieve the object, the semiconductor device according to the present invention is a semiconductor device which includes (i) a semiconductor substrate on which an active element is formed and (ii) a light transmitting member provided on an active-element-formed face of the semiconductor substrate so as to have an interval from the active element, the semiconductor device having a space between the active-element-formed face and the light transmitting member, and the semiconductor device including: a spacer layer formed around the active element on the semiconductor substrate so as to form the space; and an adhesive layer for attaching the light transmitting member to the spacer layer.

With the arrangement, the spacer layer is formed around the active element on the semiconductor substrate. Therefore, by combining the light transmitting member to the spacer layer via the adhesive layer, a space is made between the semiconductor substrate and the light transmitting member so as to be positioned at a region where the active element is disposed. Further, with the arrangement, because the spacer layer is combined to the light transmitting member via the adhesive layer, it is possible to combine the semiconductor substrate to the light transmitting member with a small load. Further, with the arrangement, because the spacer layer is formed on the semiconductor substrate, it is unnecessary to superimpose the pattern of the light transmitting member with the pattern of the spacer layer. Therefore, the light transmitting member can be combined to the spacer layer merely by superimposing their outlines.

Further, in order to achieve the object, a method according to the present invention is a method for producing the semiconductor device, the method including the step of performing, through screen printing, pattern formation of a spacer layer and an adhesive layer.

With the arrangement, it is unnecessary to use an expensive photosensitive resin material unlike a case where pattern formation is performed through photolithography. As a result, per-piece cost of a material becomes inexpensive. In conventional production methods, because the photosensitive resin material cures after formation of a pattern, a pressure of 1 through 2 MPa is necessary for combining the material to the wafer. On the other hand, in the method according to the present invention, the pattern of the spacer layer is formed through screen printing, the pattern is cured, and then the pattern of the adhesive layer is formed. Therefore, resin for the combination is not cured, and accordingly it is possible to combine the resin to the wafer with a load that is not more than 0.5 MPa.

For a fuller understanding of the nature and advantages of the invention, reference should be made to the ensuing detailed description taken in conjunction with the accompanying drawings.

### BRIEF DESCRIPTION OF THE DRAWINGS

FIG. 1(a) is a plan view illustrating a structure of a semiconductor device (CCD-CSP) according to an embodiment of the present invention.

FIG. 1(b) is a longitudinal sectional view illustrating the structure of the semiconductor device.

FIGS. 2(a) through 2(d) are plan views illustrating structures of semiconductor devices respectively having different grooves.

FIGS. 3(a) through 3(g) are longitudinal sectional views illustrating steps for producing the semiconductor device.

FIG. 4 is a longitudinal sectional view illustrating formation of the spacer layer through screen printing.

FIG. 5(a) is a longitudinal sectional view illustrating how to cut out a semiconductor device formed on a wafer.

FIG. 5(b) is a longitudinal sectional view illustrating a semiconductor device obtained by cutting out.

FIG. 6 is a longitudinal sectional view illustrating a structure of a conventional CCD package.

FIG. 7 is a longitudinal sectional view illustrating a structure of a conventional CCD module.

### DESCRIPTION OF THE EMBODIMENTS

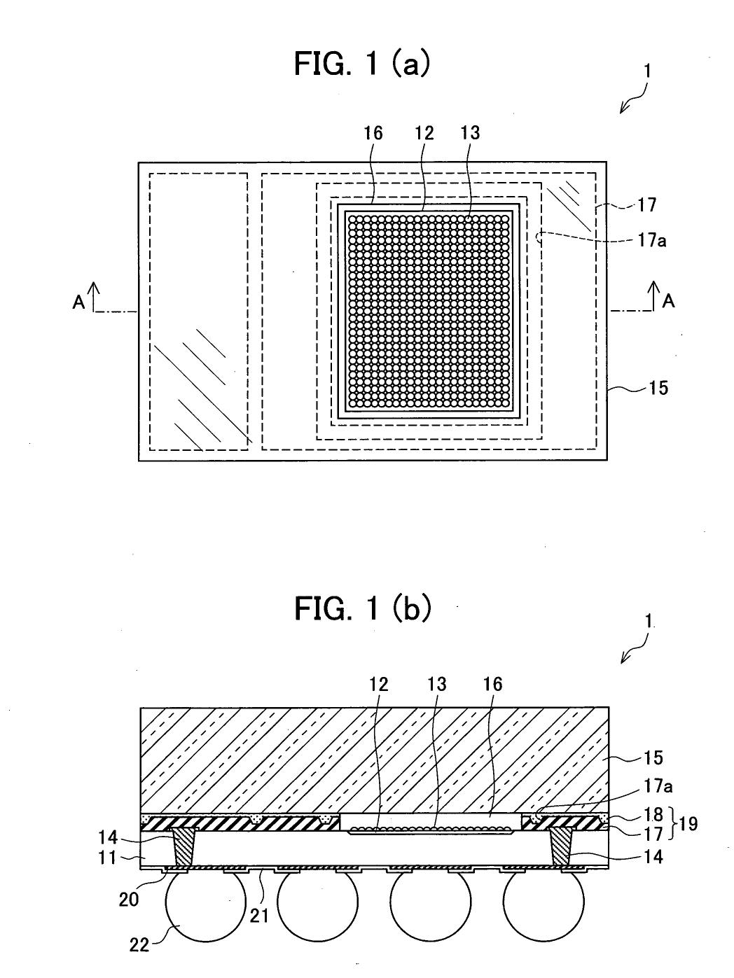

An embodiment of the present invention is explained below with reference to FIGS. 1 through 5.

FIG. 1(a) is a plan view illustrating a structure of a semiconductor device 1 according to an embodiment of the present invention. FIG. 1(b) is a longitudinal sectional view illustrating the structure of the semiconductor device 1.

As illustrated in FIGS. 1(a) and 1(b), the semiconductor device 1 includes a semiconductor substrate 11 whose shape is rectangular when seen in a plan view. The semiconductor substrate 11 is a flat plate made of Si for example. An imaging element 12 whose shape is rectangular when seen in a plan view is formed on one side of the semiconductor substrate 11. The imaging element 12 is made by arraying a plurality of pixels that serve as a light reception sensor. A micro lens section 13 is formed on a face having the imaging element 12 thereon (corresponding to an active-element-formed face recited in claims). In order to increase a light collection ratio of the imaging element 12, the micro lenses of the micro lens section 13 are arrayed so that a micro lens corresponds to a pixel of the imaging device 12 one by one.

Here, it is assumed that the front face of the semiconductor substrate 11 is one face on which the imaging element 12 is formed and the back face of the semiconductor substrate 11 is the other face on which the imaging element 12 is not formed. The semiconductor substrate 11 includes a plurality of penetrating electrodes 14 each of which penetrates the semiconductor substrate 11 from the front face to the back face. The penetrating electrodes 14 are disposed so as to have suitable intervals among them and are disposed so as to surround the imaging element 12 and the micro lens section 13 with a suitable interval from the imaging element 12 and the micro lens section 13. The number and the disposition of the penetrating electrodes 14 are set according to necessity of wires for the imaging element 12.

There is formed on the semiconductor device 1 a glass lid 15 (light transmitting material) having a rectangular flat shape, whose size is substantially the same as that of the semiconductor substrate 11 when seen in a plan view. The semiconductor substrate 11 is combined to the glass lid 15 by use of a sealing material section 19 that is made of a spacer layer 17 and an adhesive layer 18. The spacer layer 17 is provided so as to make a space 16 between the glass lid 15 and the micro lens section 13. Further, the adhesive layer 18 is made of an adhesive that attaches the glass lid 15 and the spacer layer 17.

It is preferable that the glass lid 15 is a glass coated by an infrared ray cut filter. With the glass, it is possible for a light reception sensor module constituted of the semiconductor device 1 to detect incident light without an infrared ray.

Note that the sealing material section 19 is formed on a peripheral section of the front face of the semiconductor substrate 11 so that the sealing material section 19 has a suitable interval from the imaging element 12 and the micro lens section 13. Further, the sealing material section 19 seals peripheral sections of the semiconductor substrate 11 and the glass lid 15. As a result, the imaging element 12 and the micro lens section 13 provided between the semiconductor substrate 11 and the glass lid 15 are free from attachment of foreign substances or physical contacts.

Further, a groove 17a is formed on the spacer layer 17. The groove 17a serves as a dam for preventing the adhesive layer 18 from entering an active element (imaging element 12) in the space 16 when the glass lid 15 is combined to the spacer layer 17. It is preferable that: in principle, the direction of the groove 17a is parallel to that of each periphery of the imaging element 12. When the groove 17a is formed in this direction, the groove 17a can prevent most of the adhesive which spreads upon combining (pressing) the glass lid 15 to the spacer layer 17 from entering the space 16. On the other hand, when the groove 17a is formed in a direction vertical to each periphery of the imaging element 12, it is impossible to prevent the entry of the adhesive.

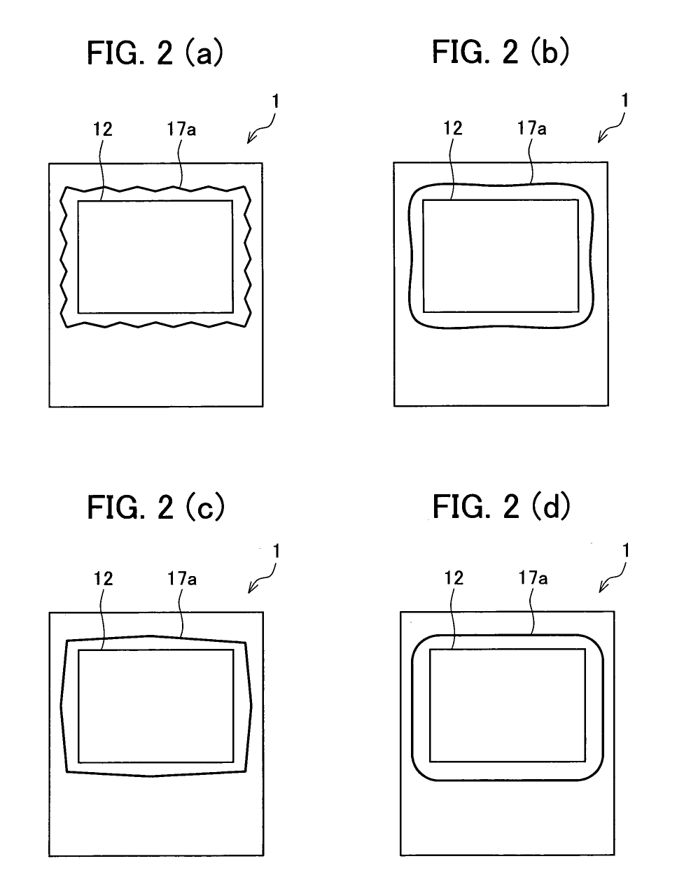

Further, the shape of the groove 17a is not limited to a straight line parallel to each periphery of the imaging element 12, as illustrated in FIG. 1(a). FIGS. 2(a) through 2(d) are examples of the shape of the groove 17a.

The groove 17a illustrated in FIG. 2(a) has such a zigzag shape that short lines which are inclined to each periphery of the imaging element 12 so as to extend in different directions are alternatively positioned.

The groove 17a illustrated in FIG. 2(b) is substantially parallel to each periphery of the imaging element 12 so as to have a mild curve over all. To be specific, the groove 17a is formed so that a portion facing a central portion of each periphery of the imaging element 12 is slightly nearer to the periphery of the imaging element 12 than corners positioned on both sides of the foregoing portion.

The groove 17a illustrated in FIG. 2(c) is formed in such a linear manner that: a portion facing a central portion of each periphery of the imaging element 12 is positioned farthest from the periphery of the imaging element 12, and the groove 17a comes nearer to each periphery of the imaging device 12 as each straight line extends nearer to corners of the groove 17a.

The groove 17a illustrated in FIG. 2(d) is formed so as to be a line parallel to each periphery of the imaging device 12 as with the groove 17a illustrated in FIG. 1 except that each of portions facing four corners of the imaging element 12 has a round shape.

As described above, the groove 17a may be a combination of lines or a curve as long as the groove 17a has a shape which prevents the adhesive from entering the space 16 (as long as the groove 17a is not vertical to each periphery of the imaging element 12).

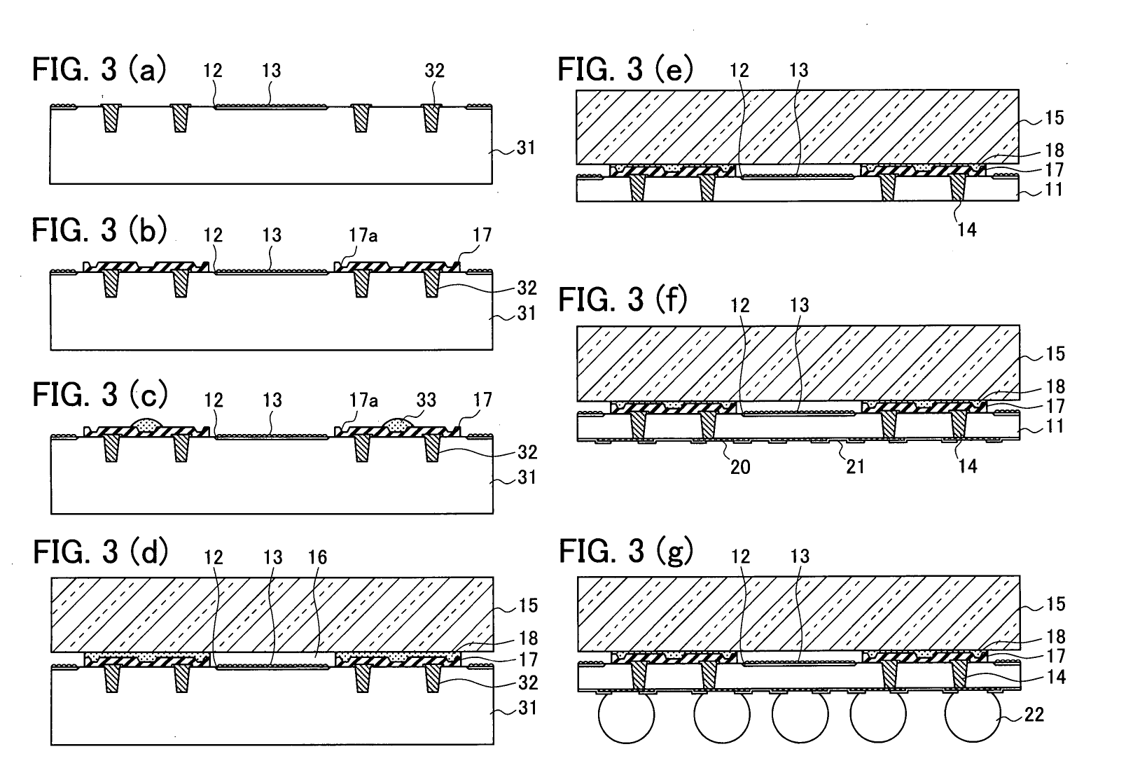

Next, with reference to FIGS. 3 through 5, the following explains how to produce the semiconductor device 1 as a CCD-CSP (Chip Size Package).

First, as illustrated in FIG. 3(a), (i) the imaging element 12 on which the micro lens section 13 is formed and (ii) embedded electrodes 32 acting as the penetrating electrodes 14 are formed on a front face of a wafer 31.

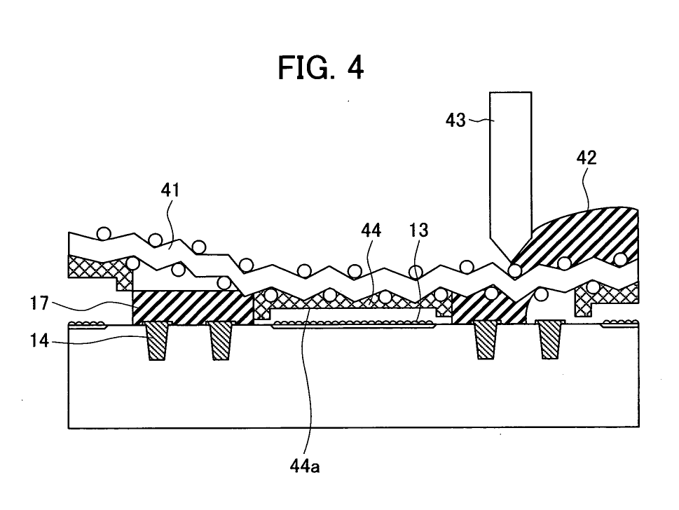

Next, as illustrated in FIG. 3(b), epoxy resin in a paste form is transferred onto the front face of the wafer 31 through screen printing so as to cover the embedded electrodes 32, thereby forming a pattern. Then, the pattern is cured so as to form the spacer layer 17. To be specific, as illustrated in FIG. 4, the spacer layer 17 is formed by putting down, by a squeegee 43, a spacer resin 42 (epoxy resin) applied on a stainless mesh 41. Next, the epoxy resin in a paste form is transferred through screen printing, thereby forming a pattern of the adhesive layer 18 used for the combination. As a result, unlike conventional producing methods, it is possible to combine the glass lid 15 to the spacer layer 17 at a pressure being not more than 0.5 MPa without curing the resin for the combination.

Further, it is preferable that the spacer layer 17 is made of epoxy resin, 60 through 90% of which is filler and whose thermal expansion coefficient is not more than 20 ppm/° C. As a result, the difference in thermal expansion between (i) the spacer layer 17 and (ii) the semiconductor substrate 11 and the glass lid 15 becomes small, thereby preventing warpage of the semiconductor substrate 11 or breakage of the glass lid 15.

The depth and width of the groove 17a formed on the spacer layer 17 are variable by adjustment of the pattern width of a screen mask for printing and thixotropy of epoxy resin. Further, as illustrated in FIG. 4, a concave section 44a is provided in a mask film face 44 (a face opposite to the micro lens section 13) of a screen mask opposite to the micro lens section 13. As a result, it is possible to prevent the mask film from directly touching the micro lens section 13, thereby preventing damage of the micro lens section 13 in printing.

Next, as illustrated in FIG. 3(c), an adhesive 33 provided as the adhesive layer 18 is applied onto the spacer layer 17. The adhesive 33 is applied by transferring an epoxy adhesive in a liquid or paste form through printing. At that time, too, a concave section is provided in the mask film face of the screen mask facing the micro lens section 13. As a result, it is possible to prevent the mask film from directly touching the micro lens section 13, thereby preventing damage of the micro lens section 13 in printing.

Alternatively, the adhesive layer 18 may be formed by applying the adhesive through lithography by a dispenser.

Further, it is preferable that the adhesive layer 18 (adhesive 33) is made of epoxy resin whose glass-transition temperature is 80 through 100° C. As a result, even when heat being approximately 150° C. is applied in steps after the step of combining the glass lid 15 to the spacer layer 17, the adhesive layer 18 becomes flexible, so that the glass lid 15 is less likely to break.

Next, as illustrated in FIG. 3(d), the glass lid 15 is combined onto the spacer layer 17 through the following procedure. First, the wafer 31 having the adhesive 33 applied on the spacer layer 17 is fixed on a stage so that the adhesive 33 faces upward, and the glass lid 15 is put on the wafer 31. At that time, the adhesive 33 is pressed so as to spread on the spacer 17, thereby forming the adhesive layer 18. After that, the adhesive 33 is tentatively cured and then firmly cured, thereby combining the glass lid 15 to the wafer 31 via the spacer layer 17. As a result, the space 16 is made between the imaging element 12 and the glass lid 15.

Further, because the groove 17a provided on the spacer layer 17 controls spread of the adhesive 33 on the spacer layer 17, the adhesive 33 does not greatly extend to the space 16. Further, the adhesive 33 is not cured in the same manner as a case where photosensitive resin for the combination is cured through a photo method used in conventional arts. Therefore, it is unnecessary to apply a load of 3t per 8-inch wafer and it is possible to combine the glass lid 15 to the wafer 31 with a load being not more than a tenth of 3 t per 8-inch wafer. As a result, the wafer 31 is free from damage. Further, because the pattern is formed on the wafer 31, it is unnecessary to superimpose the pattern of the glass lid 15 with the pattern of the wafer 31. Therefore, it is possible to combine the glass lid 15 to the wafer 31 merely by superimposing their outlines. As a result, it is possible to arrange a combining machine at lower cost.

Next, as illustrated in FIG. 3(e), the back face of the wafer 31 is removed so that the embedded electrodes 32 are exposed, thereby forming the semiconductor substrate 11 and the penetrating electrodes 14. The back face of the wafer 31 is removed through general back-face polishing.

After the back-face polishing, the back face of the wafer 31 may be polished through CMP (Chemical Mechanical Polishing) or etched through RIE (Reactive Ion Etching) in order to rinse the polished face. In this step, the glass lid 15 combined to the wafer 31 reinforces the wafer 31.

Next, as illustrated in FIG. 3(f), a back face wiring 20 extending from the penetrating electrodes 14 to a predetermined land section is formed in the following steps. First, there is formed an insulating layer (not shown) that electrically insulates the wafer 31 from the rewiring, and windows are opened on the insulating layer so that portions corresponding to the penetrating electrodes 14 are electrically connected with the back face wiring 20. A photoconductive organic film is applied onto the back face of the wafer 31 and exposed and developed so as to open necessary windows, and then the organic film is cured by thermal cure, thereby forming the insulating layer.

At that time, the present invention may be arranged so that an inorganic film such as SiO₂ or Si₃N₄ is formed as the insulating layer, resist is applied onto the insulating layer so as to expose and develop the insulating film, and windows are opened on the insulating film through etching.

Next, there is formed the back face wiring 20 expanding from the opening of the insulating layer to the land section. The back face wiring is formed in such a -manner that a Ti layer and a Cu layer serving as both a metal plating seed layer and a barrier metal layer are formed through sputtering, resist is applied onto the layers and exposed and developed so as to open windows on which Cu plating wiring is to be formed, the wiring is formed through electrolysis Cu plating, the resist is removed, and unnecessary parts of the sputtering layer are removed through etching.

At that time, the wiring may be formed in such a manner that: a metal layer (such as Cu, CuNi, and Ti) constituting the wiring is formed through sputtering, resist is applied onto the metal layer and exposed and developed, and the wiring is formed on the metal layer through etching. Then, a back face protecting film 21 for protecting the back face wiring 20 is formed. The back face protecting film 21 is formed in such a manner that: a photosensitive organic film is applied onto the back face of the wafer 31 and exposed and developed so as to open windows on the land section, and the organic film is cured through thermal cure. At that time, the back face protecting film 21 may be formed in such a manner that: an inorganic film such as SiO₂ or Si₃N₄ is formed, resist is applied onto the inorganic film and exposed and developed, and windows are opened on the inorganic film through etching.

Next, as illustrated in FIG. 3(g), solder electrodes 22 are formed. At that time, rosin flux is applied onto the land section of the back face, solder balls made of Sn—Ag—Cu are attached onto the land section, a thermal treatment is performed on the back face, and the flux is washed and removed. Alternatively, the solder electrodes 22 may be formed by printing solder pastes of Sn—Ag—Cu on the land section of the back face and performing the thermal treatment on the land section.

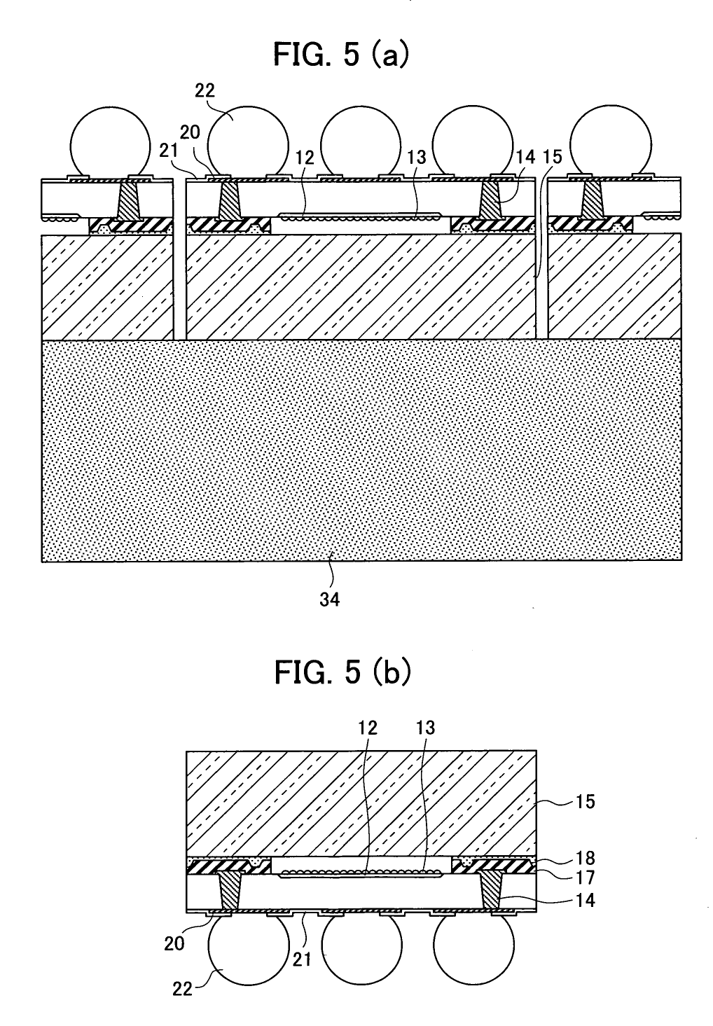

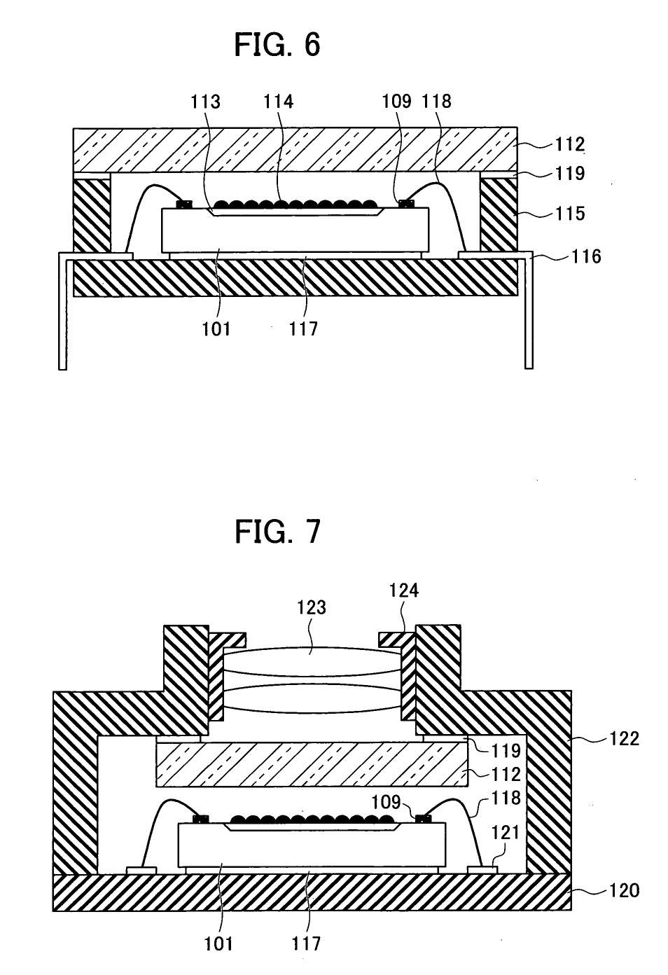

Lastly, as illustrated in FIG. 5(a), the semiconductor substrate 11 and the glass lid 15 are divided into the semiconductor devices 1 through the following processes. First, the semiconductor substrate 11 and the glass lid 15 are cut by a dicing device so that the glass lid 15 is combined to the dicing sheet 34. As a result, the semiconductor device 1 illustrated in FIG. 5(b) can be obtained.

Through the above steps, a CCD-CSP can be formed.

In this way, in the semiconductor device 1 according to the present invention, because the spacer layer 17 is formed so as to surround the imaging element 12 on the semiconductor substrate 11, the glass lid 15 is combined to the spacer layer 17 via the adhesive layer 18. As a result, the space 16 is formed between the semiconductor substrate 11 and the glass lid 15 so as to locate the imaging element 12. Further, because the spacer layer 17 is combined to the glass lid 15 by the adhesive layer 18, it is possible to combine the glass lid 15 to the semiconductor substrate 11 with a small load. Besides, because the spacer layer 17 is formed on the semiconductor substrate 11, it is unnecessary to superimpose patterns when the glass lid 15 is combined to the spacer layer 17. It is possible to combine the glass lid 15 to the semiconductor substrate 11 merely by superimposing their outlines.

Note that the semiconductor device 1 exemplified in the present embodiment is suitable for a CSP (Chip size package) of a CCD image sensor including the semiconductor substrate 11 on which the imaging element 12 serving as a semiconductor element is formed. However, the present invention is not limited to this. For example, the present invention may be a semiconductor device including a semiconductor substrate on which a light reception element and/or a light emitting element are formed.

Further, it is preferable to arrange the semiconductor device according to the present invention so that: the spacer layer has a groove which prevents an adhesive constituting the adhesive layer from entering the active element when the light transmitting member is combined to the spacer layer. As a result, when the light transmitting member is combined to the spacer layer, the spreading adhesive flows in the groove. Therefore, it is possible to prevent the adhesive from entering the active element. Further, because the groove is formed so as to be substantially parallel to the periphery of the active element, more amounts of the adhesive flow in the groove. Therefore, it is possible to prevent the adhesive from spreading without fail.

It is preferable to arrange the semiconductor device according to the present invention so that: the spacer layer is made of epoxy resin, 60 through 90% of which is filler and whose thermal expansion coefficient is not more than 20 ppm/° C. As a result, the difference in thermal expansion between (i) the spacer layer and (ii) the semiconductor substrate and the light transmitting member becomes small. Therefore, it is possible to prevent warpage of the semiconductor substrate or breakage of the light transmitting member.

It is preferable to arrange the semiconductor device according to the present invention so that: the adhesive layer is made of epoxy resin whose glass-transition temperature is 80 through 100° C. As a result, even when heat being approximately 150° C. is applied in steps after the step of combining the light transmitting member to the spacer layer, the adhesive layer become flexible, so that the light transmitting member is less likely to break.

It is preferable to arrange the semiconductor device according to the present invention so that the active element is an optical light reception sensor, such as a CCD or CMOS image sensor, having a light reception section, and a micro lens is formed on the light reception section. As a result, the semiconductor device can be used as the optical light reception sensor module.

It is preferable to arrange the semiconductor device according to the present invention so that: the light transmitting member is a glass coated by an infrared ray cut filter. As a result, the light reception sensor module can detect an incident light without any infrared ray.

It is preferable to arrange the semiconductor device according to the present invention so as to include a penetrating electrode that penetrates the semiconductor substrate from the active-element-formed face to a face opposite to the active-element-formed face. As a result, in the semiconductor device including the penetrating electrode, it is possible to combine the semiconductor substrate to the light transmitting member with a small load and by superimposing the outlines.

Further, it is preferable to arrange the method according to the present invention so that: in a mask film face of a screen mask used in the screen printing, a concave section is formed at a region opposite to a physically weak portion formed over the active element. In the conventional production methods, when the adhesive layer is formed not on the optical glass but on the wafer, it is unnecessary to superimpose the patterns. However, because a resin layer is temporarily formed over a micro lens, foreign substances may adhere to the micro lens or the micro lens may get scratched. On the other hand, with the method according to the present invention, because the screen mask having the concave section in the mask film face is used, a physically weak portion (e.g. micro lens) formed on the active element does not touch the screen mask. Therefore, it is possible to form the adhesive layer on the semiconductor substrate without damaging the physically weak point. As a result, when the concave section is formed in the mask film face of a section that touches a micro lens in a CCD for example, it is possible to reduce damage of the micro lens which is caused by the touch of the mask.

As described above, the semiconductor device according to the present invention includes: a spacer layer formed around the active element on the semiconductor substrate so as to form the space; and an adhesive layer for attaching the light transmitting member to the spacer layer. Therefore, it is possible to combine the semiconductor substrate to the light transmitting member with a small load and by superimposing the outlines.

Further, the method according to the present invention for producing the semiconductor device includes the step of performing, through screen printing, pattern formation of a spacer layer and an adhesive layer. As a result, it is possible to reduce costs required in producing the semiconductor device. Further, by providing the concave section in the mask film face of a screen mask used for printing that touches the micro lens, it is possible to prevent the mask film from directly touching the physically weak section formed on the face on which the active element such as the micro lens is formed. Therefore, it is possible to prevent the micro lens from being damaged in printing.

In producing the semiconductor device according to the present invention, the semiconductor substrate is combined to the glass lid (light transmitting member) with a small load and with easiness. Therefore, the semiconductor device according to the present invention is favorably used for a light reception sensor such as a CCD and a CMOS imager.

The invention being thus described, it will be obvious that the same way may be varied in many ways. Such variations are not to be regarded as a departure from the spirit and scope of the invention, and all such modifications as would be obvious to one skilled in the art are intended to be included within the scope of the following claims.

What is claimed is:

1. A semiconductor device which includes (i) a semiconductor substrate on which an active element is formed and (ii) a light transmitting member disposed over an active-element-formed face of the semiconductor substrate so as to have an interval from the active element, said semiconductor device having a space between the active-element-formed face and the light transmitting member,
said semiconductor device comprising:
a spacer layer formed around the active element on the semiconductor substrate so as to form the space; and
an adhesive layer for combining the light transmitting member to the spacer layer.

2. The semiconductor device as set forth in claim 1, wherein the spacer layer has a groove which prevents an adhesive constituting the adhesive layer from entering the active element when the light transmitting member is combined to the spacer layer.

3. The semiconductor device as set forth in claim 2, wherein the groove is formed so as to be substantially parallel to a periphery of the active element.

4. The semiconductor device as set forth in claim 1, wherein the spacer layer is made of epoxy resin, 60 through 90% of which is filler and whose thermal expansion coefficient is not more than 20 ppm/° C.

5. The semiconductor device as set forth in claim 1, wherein the adhesive layer is made of epoxy resin whose glass-transition temperature is 80 through 100° C.

6. The semiconductor device as set forth in claim 1, wherein the active element is an optical light reception sensor having a light reception section, and a micro lens is formed on the light reception section.

7. The semiconductor device as set forth in claim 6, wherein the light transmitting member is a glass coated by an infrared ray cut filter.

8. The semiconductor device as set forth in claim 1, comprising a penetrating electrode that penetrates the semiconductor substrate from the active-element-formed face to a face opposite to the active-element-formed face.

9. A method for producing a semiconductor device which includes (i) a semiconductor substrate on which an active element is formed and (ii) a light transmitting member disposed over an active-element-formed face of the semiconductor substrate so as to have an interval from the active element, said semiconductor device having a space between the active-element-formed face and the light transmitting member,
said method comprising the step of performing, through screen printing, pattern formation of:
a spacer layer formed around the active element on the semiconductor substrate so as to form the space; and
an adhesive layer for combining the light transmitting member to the spacer layer.

10. The method as set forth in claim 9, wherein: in a mask film face of a screen mask used in the screen printing, a concave section is formed at a region opposite to a physically weak portion formed over the active element.
